(19) United States
(12) Patent Application Publication
(10) Pub. No.: US 2013/0074899 A1
(43) Pub. Date: Mar. 28, 2013

(54) APPARATUS FOR THERMOELECTRIC GENERATION OF ELECTRICAL ENERGY

(71) Applicants: Martin Kurth, Kandern (DE); Christian Fräulin, Waldkirch (DE)

(72) Inventors: Martin Kurth, Kandern (DE); Christian Fräulin, Waldkirch (DE)

(73) Assignee: A. RAYMOND ET CIE, Grenoble (FR)

(21) Appl. No.: 13/701,906

(22) PCT Filed: May 24, 2011
(86) PCT No.: PCT/EP2011/058425

§ 371 Date: Dec. 4, 2012

(30) Foreign Application Priority Data
Jun. 8, 2010 (DE) 102010022968.7

(51) Int. Cl. H01L 35/30

(52) U.S. Cl. CPC H01L 35/30
USPC 136/205

(57) ABSTRACT

In the case of an apparatus for thermoelectric generation of electrical energy, a base part and an opposing piece are provided, between which a thermoelectric element is arranged and which can be connected to one another as a physical unit via latching elements which are formed on an attachment adaptor. The thermoelectric element can therefore be fixed with relatively low mechanical loads, and the physical unit can be arranged in a compact form at an installation location.

### CROSS-REFERENCE TO RELATED APPLICATION

This application is a U.S. National Phase Patent Application based on International Application No. PCT/EP2011/058425 filed May 24, 2011, which claims priority to German Patent Application No. 10 2010 022 968.7 filed Jun. 8, 2010, the entire disclosures of which are hereby explicitly incorporated by reference herein.

### BACKGROUND OF THE INVENTION

1. Field of the Invention

The present invention relates to an apparatus for thermoelectric generation of electrical energy.

2. Description of the Related Art

Known from, for example, EP 1 160 863 B1, U.S. Pat. No. 6,431,259 B2 or DE 25 39 379 A1 are apparatuses in which an electronic component is attached to a heat conducting body via clamping means.

### SUMMARY OF THE INVENTION

The present invention provides an apparatus for thermoelectric generation of electrical energy that is distinguished by relatively high efficiency and is easy to deploy.

By virtue of the fact that in the apparatus according to the invention, the thermoelectric element is fitted in between a base part and a counterpart, which themselves in turn are connected to each other via the latching elements formed on the attachment adapter, the apparatus is very easy to assemble and yet has relatively high efficiency.

In one form of thereof, the present invention provides an apparatus for thermoelectric generation of electrical energy, including a thermoelectric element; a base part; an attachment adapter having latching elements on both faces of an adapter plate penetrated by an adapter opening; and a counterpart, wherein the latching elements are adapted to maintain the base part and the counterpart such that the base part and the counterpart are in contact with the thermoelectric element.

### BRIEF DESCRIPTION OF THE DRAWINGS

The above mentioned and other features and objects of this invention, and the manner of attaining them, will become more apparent and the invention itself will be better understood by reference to the following description of embodiments of the invention taken in conjunction with the accompanying drawings, wherein:

FIG. 1 is an exploded perspective view of an exemplary embodiment of an apparatus according to the invention that is intended for use with a fluid line piece;

FIG. 2 is a perspective view of the exemplary embodiment according to FIG. 1 during an assembly step;

FIG. 3 is a perspective view of the exemplary embodiment according to FIG. 1 during another assembly step, subsequent to the arrangement of FIG. 2;

FIG. 4 is a perspective view of the exemplary embodiment according to FIG. 1 in a final assembled arrangement; and

FIG. 5 is a longitudinal section of the exemplary embodiment according to FIG. 1 in a final assembled arrangement according to FIG. 4.

Corresponding reference characters indicate corresponding parts throughout the several views. Although the exemplifications set out herein illustrate embodiments of the invention, in several forms, the embodiments disclosed below are not intended to be exhaustive or to be construed as limiting the scope of the invention to the precise forms disclosed.

### DETAILED DESCRIPTION

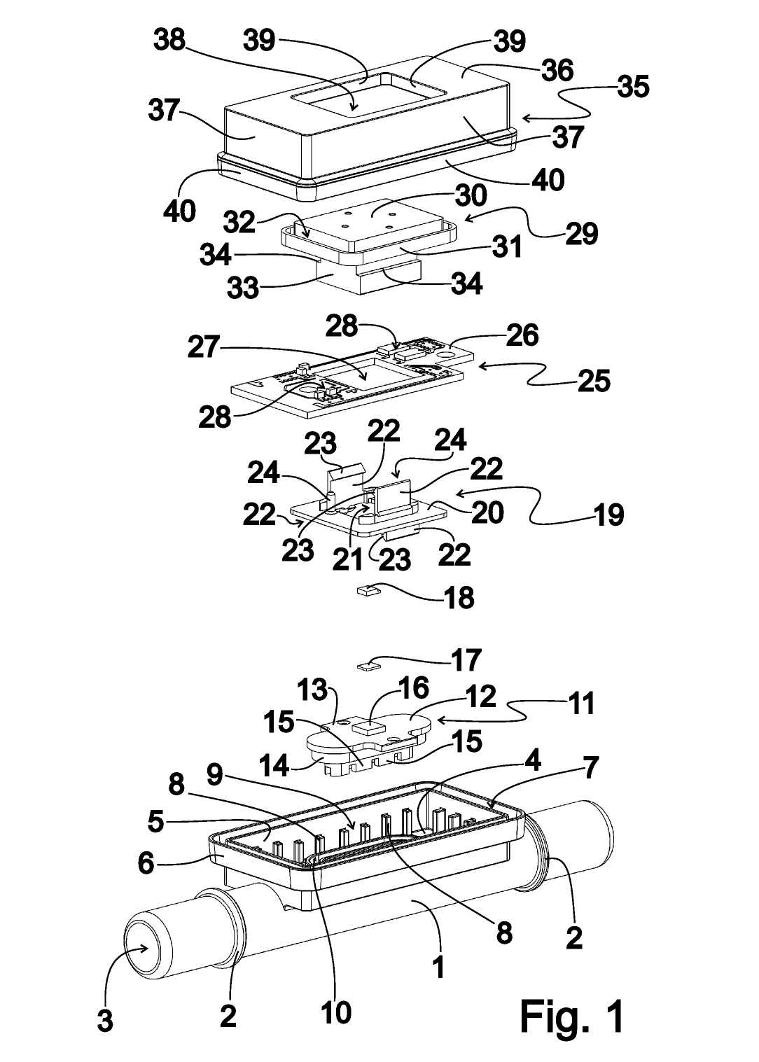

FIG. 1 is an exploded perspective view of an exemplary embodiment of an apparatus according to the invention for thermoelectric generation of electrical energy. Illustrated in FIG. 1, as a receiving body, is a fluid line piece 1 which can be fitted by two ends into a fluid line system (not shown in FIG. 1) by the rearward engagement of latching collars 2, and which has a flow-through conduit 3 extending between the two ends of the fluid line piece 1. Formed on the fluid line piece 1 between the latching collars 2 is a baseplate 4, surrounded by an inner wall 5. Formed at and in spaced relation to the edge of inner wall 5 directed away from fluid line piece 1 is an outer wall 6, such that an insertion channel 7 is present between the inner wall 5 and the outer wall 6.

Formed on the mutually facing inner sides of inner wall 5 are a number of abutment bars 8, which extend away from the baseplate 4 and terminate at a distance from the edge of inner wall 5 that is directed away from the fluid line piece 1. In a receiving space 9 surrounded by inner wall 5 there is a circumferentially closed base-part receiving structure 10, which is disposed centrally with respect to inner wall 5 and terminates at the height of baseplate 4 corresponding to approximately half the length of the abutment bars 8.

Also present is a base part 11 that is a good thermal conductor, which comprises a baseplate 12; latching tongues 13, as catch elements, that protrude laterally from opposite sides of the baseplate 12; an immersing edge 14 disposed on one side of the baseplate 12 and encircling a number of immersing tongues 15; and a support pedestal 16, which is disposed on a cover side of the baseplate 12 directed away from the immersing edge 14 and whose face directed away from the baseplate 12 is raised above the cover side of the baseplate 12.

In the exemplary embodiment of FIG. 1, the apparatus of the invention is also equipped with an intermediate element 17 that is a good thermal conductor, formed, for example, by a plastically deformable film or a layer of high-viscosity adhesive.

The apparatus according to the invention further comprises a thermoelectric element 18, which has approximately the dimensions of the working face of the support pedestal 16 and of the intermediate element 17. The thermoelectric element 18 is configured as relatively thin and is not able to withstand very high mechanical loads.

The apparatus according to the invention further comprises an attachment adapter 19, which includes an adapter plate 20 of approximately square shape. Formed in the center of adapter plate 20 is an adapter opening 21, which is dimensioned to be at least as large as the support pedestal 16 and in the exemplary embodiment of FIG. 1 also has an approximately square shape. Formed as latching elements on both faces of the adapter plate 20, at opposite edge sides of the adapter recess 21, are resilient flat counterpart latching hooks 22, which extend away from adapter plate 20 and each of which is configured with a respective latching nose 23 at its end directed away from adapter plate 20. The attachment adapter 19 also comprises alignment pins 24, which are disposed diagonally to each other and extend from a cover side of the adapter plate 20 and away therefrom.

The exemplary embodiment of an apparatus according to the invention as illustrated in FIG. 1 also comprises a circuit board 25 formed with a board panel 26, in the center of which is a board aperture 27. The board aperture 27 is so dimensioned as to permit through-passing engagement by the counterpart latching hooks 22 disposed next to the alignment pin 24 and by the alignment pins 24, which prevent the circuit board 25 from shifting in the plane of the adapter plate 20 parallel to the flat sides of the counterpart latching hooks 22. The board panel 26 is fitted with a number of electronic components 28 that are to be supplied with electrical energy by the thermoelectric element 18.

The apparatus according to the invention is also equipped with a counterpart 29 comprising a cover plate 30 of approximately rectangular shape, which is surrounded at a distance from its edges by a counterpart edge wall 31, so as to form an insertion channel 32. On one face of the cover plate 30, the counterpart 29 comprises a non-inserting pedestal 33 of approximately square shape, which is configured on each of two mutually opposite wall sides with a respective latching step 34 as a catch element.

Finally, the exemplary embodiment of an apparatus according to the invention illustrated in FIG. 1 includes a cover part 35 composed of a cover wall 36 and edge walls 37 extending perpendicularly away from the cover wall 36. Formed in the cover wall 36 is a cover wall opening 38 dimensioned such that cover plate 30 of counterpart 29 can be fitted into said cover wall opening 38. The rim of cover wall opening 38 is configured with a peripheral immersing wall 39e extending in the same direction as the edge walls 37. In addition, the edge sides of edge walls 37 directed away from the cover wall 36 are provided with a protruding immersing portion 40, which stiffen the cover part 35.

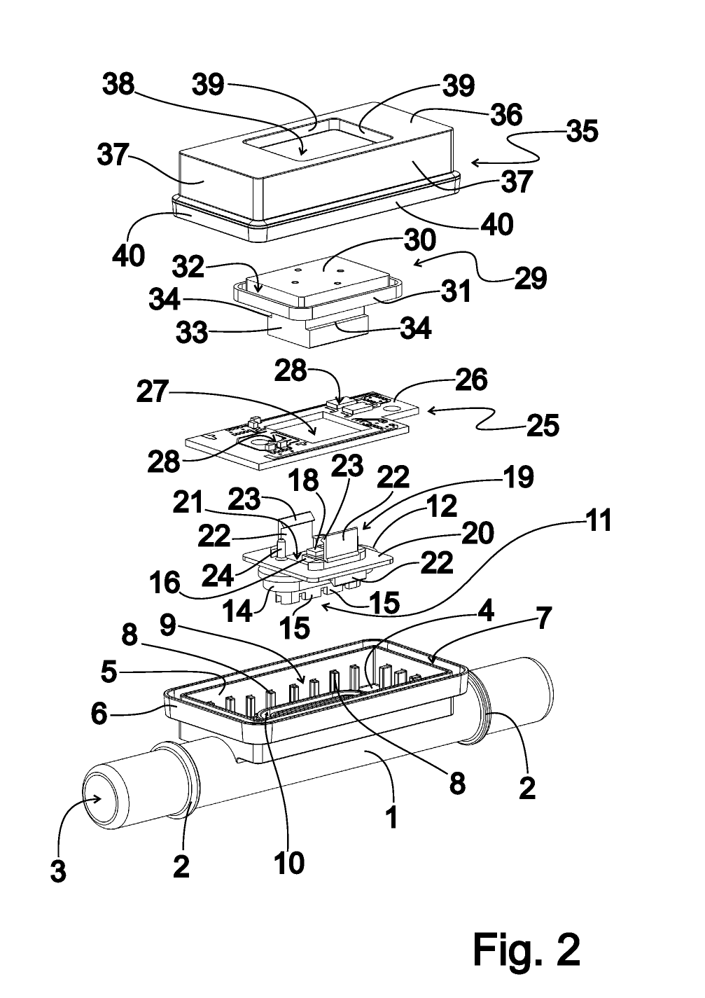

FIG. 2 is a perspective view of the exemplary embodiment of an apparatus according to the invention as depicted in FIG. 1 during an assembly step of the components described in connection with FIG. 1. In the partially assembled arrangement illustrated in FIG. 2, the thermoelectric element 18 is attached to the support pedestal 16 of the base part 11 via intermediate element 17, which serves, among other things, for subsequent tolerance compensation. The base part 11 is connected to the attachment adapter 19 by the rearward engagement of its latching tongues 13 by the latching noses 23 of the counterpart latching hooks 22, accompanied by the engagement of support pedestal 16, with thermoelectric element 18, through adapter opening 21.

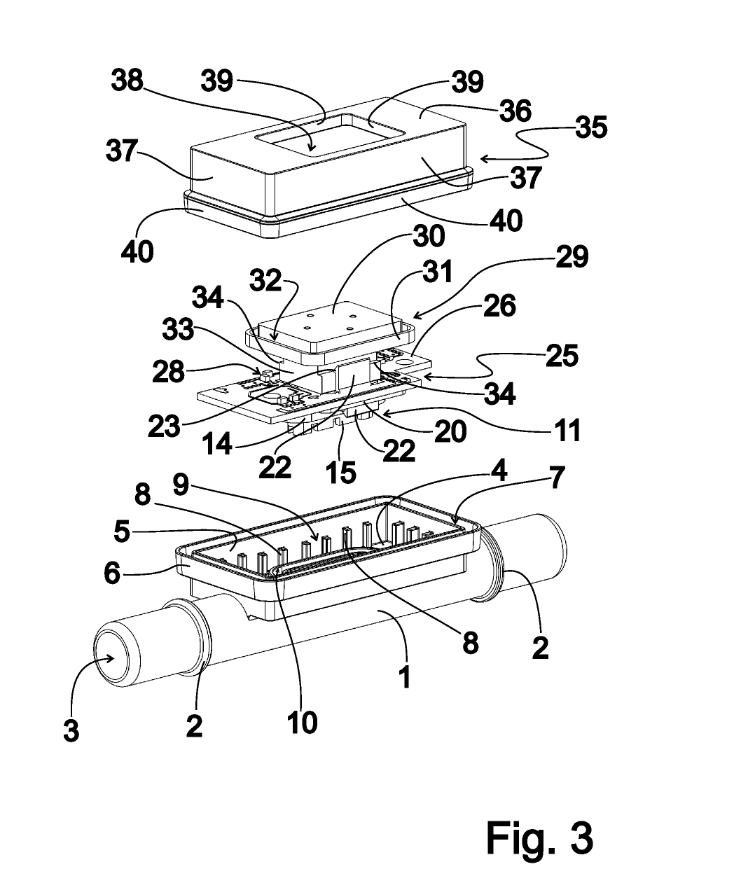

FIG. 3 is a perspective view of the exemplary embodiment of an apparatus according to the invention as illustrated in FIG. 1 in a further assembly step, subsequent to the assembly step depicted in FIG. 2. In the assembly step of FIG. 3, the circuit board 25 now rests on adapter plate 20 on the opposite side of adapter plate 20 from base part 11, with the counterpart latching hooks 22 that are directed away from base part 11 engaged through the board aperture 27, and the counterpart 29 rests on the thermoelectric element 18 (not visible in FIG. 3), an intermediate element 17 advantageously also being interposed for tolerance compensation between the thermoelectric element 18 and the face of the non-inserting pedestal 33 directed away from the cover plate 30. In the arrangement according to FIG. 3, the latching noses 23 of the counterpart latching hooks 22 directed away from the base part 11 engage behind the latching steps 34 formed on the non-inserting pedestal 33, such that the counterpart 29 is now connected to the attachment adapter 19, as well. Due to the larger dimensioning of non-inserting pedestal 33 compared to the board aperture 27, the circuit board 25 is also thereby fixed in place. The alignment pin 24 is disposed in an alignment pin opening created in the non-inserting pedestal 33, thereby also ensuring that the counterpart 29 is aligned at the proper angle relative to the attachment adapter 19.

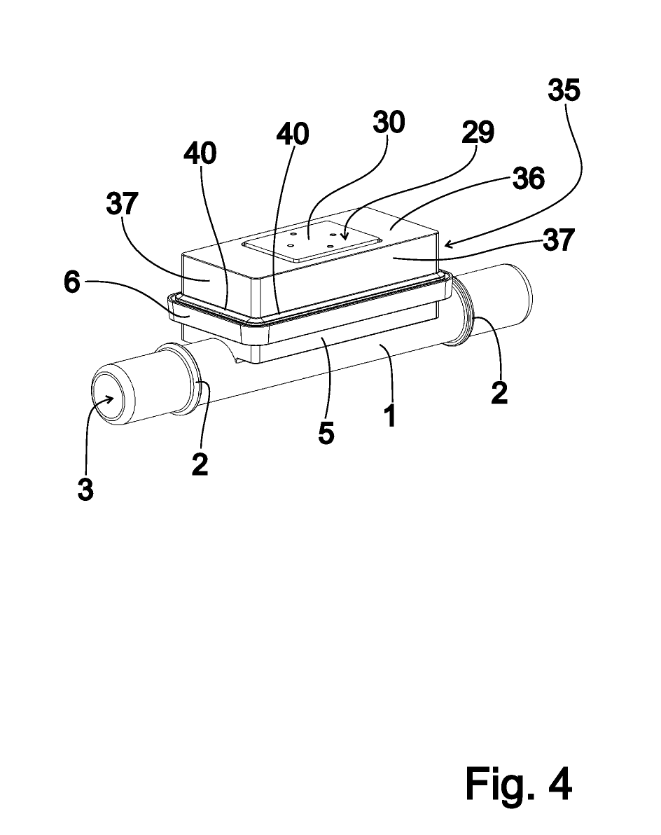

FIG. 4 is a perspective view of the exemplary embodiment according to FIG. 1 in a final assembled arrangement, in which the physical unit composed of the base part 11, the attachment adapter 19, the circuit board 25 and the counterpart 29 are inserted in the receiving space 9, and the cover part 35 with its immersing portion 40 is seated in the insertion channel 7 formed between inner wall 5 and outer wall 6. In addition, the immersing wall 39 engages in the insertion channel 32 formed on counterpart 29, such that the cover part 35 outwardly seals the receiving space 9 fluid-tight.

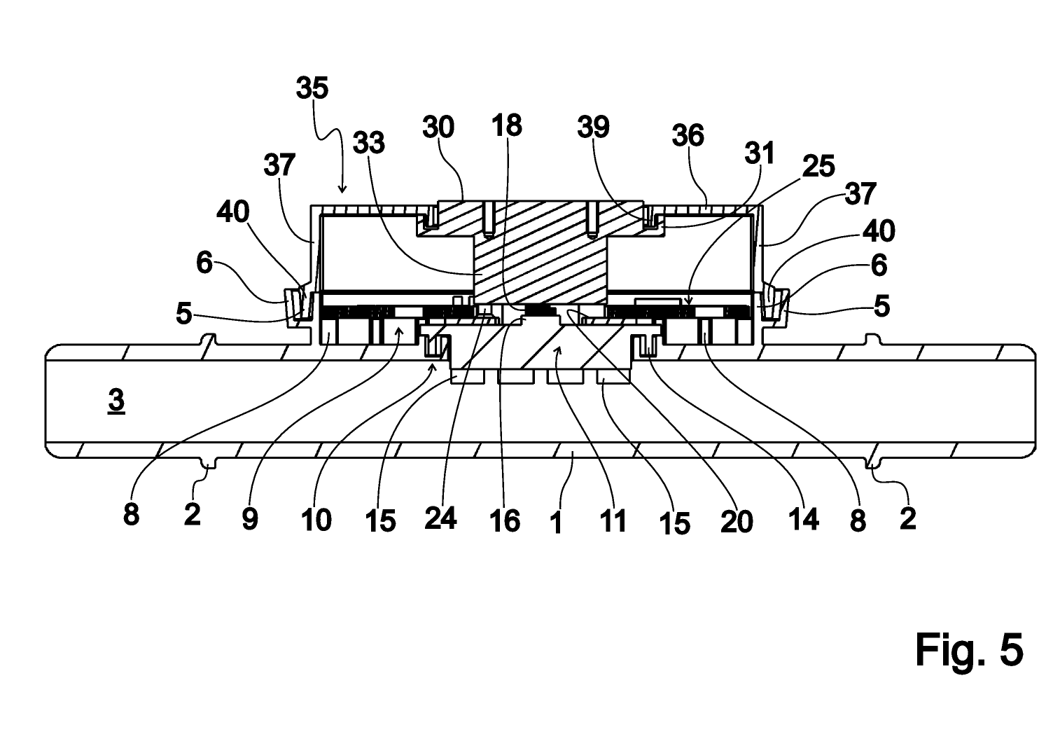

FIG. 5 is a longitudinal section of the exemplary embodiment according to FIG. 1 in the final assembled arrangement of FIG. 4. It is apparent from FIG. 5 that the immersing tongues 15 are disposed in the flow-through conduit 3, with the result that, assuming suitably high thermal conductivity for the material of the base part 11, the side of the thermoelectric element 18 facing toward the support pedestal 16 is at a first temperature that is assigned to the fluid flowing in the flow-through conduit 3.

It can also be appreciated from FIG. 5 that the immersing edge 14 engages in the base-part receiving structure 10 and thereby seals the receiving space 9 with respect to the flow-through conduit 3. The board panel 26 rests at its outer edge sides on the abutment bars 28 and is supported by them, thus ensuring mechanically stable mounting. In addition, the side of the thermoelectric element 18 facing away from the support pedestal 16 is at a second temperature that is moderated by the ambient temperature by means of counterpart 29, and which, when it differs from the first temperature, causes the thermoelectric element 18 to generate electrical energy that can be supplied to power the electrical components 28 of the circuit board 25.

While this invention has been described as having a preferred design, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

1-10. (canceled)

11. An apparatus for thermoelectric generation of electrical energy, comprising:
a thermoelectric element;
a base part;
a counterpart; and
an attachment adapter including an adapter plate having an adapter opening and latching elements on opposite faces of the adapter plate, the latching elements maintaining the base part and the counterpart in contact with the thermoelectric element.

12. The apparatus of claim 11, wherein the base part further comprises a base plate and a support pedestal extending from the base plate and including a working face on which the thermoelectric element is disposed.

13. The apparatus of claim 12, further comprising at least one deformable intermediate element disposed in a position selected from the group consisting of: between the support pedestal and the thermoelectric element, between the counterpart and the thermoelectric element, and a combination of the foregoing.

14. The apparatus of claim 11, comprising a pair of the latching elements disposed on opposite sides of the adapter opening to maintain the base part and the counterpart.

15. The apparatus of claim 11, wherein the latching elements are form as resilient latching hooks, each including a latching nose engageable behind a respective catch element of one of the base part and the counterpart.

16. The apparatus of claim 15, wherein the counterpart comprises a non-inserting pedestal including latching steps as catch elements, a base area of the non-inserting pedestal dimensioned larger than the adapter opening and being oriented facing the thermoelectric element.

17. The apparatus of claim 16, further comprising a circuit board disposed between an adapter plate of the attachment adapter and the non-inserting pedestal.

18. The apparatus of claim 11, wherein the base part is adapted to be arranged fluid-tightly in a base-part receiving structure of a receiving body.

19. The apparatus of claim 18, wherein the receiving body and the cover part are connected fluid-tightly to each other.

20. The apparatus of claim 11, wherein the counterpart is adapted to be arranged fluid-tightly in a cover opening formed in a cover part.

21. The apparatus of claim 20, wherein the receiving body and the cover part are connected fluid-tightly to each other.
